(19) United States
(12) Patent Application Publication
(10) Pub. No.: US 2007/0290728 A1
(43) Pub. Date: Dec. 20, 2007

(54) CIRCUIT AND METHOD FOR SLEW RATE CONTROL

(76) Inventor: Jui-Yuan Tsai, Tai-Nan City (TW)

Correspondence Address: NORTH AMERICA INTELLECTUAL PROPERTY CORPORATION, P.O. BOX 506, MERRIFIELD, VA, 22116, US

(21) Appl. No.: 11/761,373

(22) Filed: Jun. 12, 2007

(30) Foreign Application Priority Data
Jun. 14, 2006 (TW) 095121255

(51) Int. Cl. H03K 5/12

(52) U.S. Cl. 327/170

(57) ABSTRACT

A circuit and method for slew rate control is described. The circuit for slew rate control comprises a slew rate control circuit and an output buffer. The slew rate control circuit controls the rising slew rate and falling slew rate of an output voltage signal. The output buffer stabilizes the output voltage signal.

### CROSS REFERENCE TO RELATED APPLICATION

This application claims the priority benefit of Taiwan Patent Application Serial Number 095121255, filed on Jun. 14, 2006, the full disclosure of which is incorporated herein by reference.

### BACKGROUND OF THE INVENTION

1. Field of the Invention

This invention generally relates to an output driver circuit, and more particularly, relates to a circuit and method for output voltage slew rate control.

2. Description of the Related Art

A conventional digital output circuit 90 is composed of a set of serially connected buffers 91, e.g. inverter, as shown in FIG. 1. The digital output circuit 90 transfers a digital input signal 92 to a digital output signal 93 so as to control the slew rate of the digital output signal 93 conforming to the standards in various applications. An exemplary circuit diagram, but not limited to, of the buffers 91 is shown in FIG. 1a. The voltage slew rate of the digital output circuit 90 is determined by parasitic capacitors existed therein and loading capacitors. The voltage rising slew rate and voltage falling slew rate are regulated in many application fields, e.g. the consumer electronics control (CEC) in a high-definition multimedia interface (HDMI), and it is especially difficult to achieve requirements in the applications requiring very slow slew rate. In addition, the conventional output circuit further has the problems of nonlinear rising and falling waveforms of output signals and the waveform may vary with the load ZL connected next to the digital output circuit 90.

Another conventional output circuit is shown in FIG. 1b, in which a P-gate control circuit 94 and a N-gate control circuit 95 are added in front of the last stage of the serially connected buffers 91 so as to control gate voltages of the PMOS and NMOS transistors respectively, thereby controlling the rising and falling slope of the output voltage signals. However, the circuit shown in FIG. 1b is constructed in an open-loop; therefore, the construction still has the problems of difficulty to precisely control the slew rate of output voltage signals and of the output voltage easily affected by the load of the circuit.

According to the above-mentioned reasons, it is necessary to further improve the conventional slew rate control circuit so as to solve the difficult control problem of output voltage slew rate.

### SUMMARY OF THE INVENTION

It is an objective of the present invention to provide a circuit and method to control the slew rate of an output signal.

It is another objective of the present invention to provide a circuit and method for slew rate control to control the slew rate of an output voltage signal and stabilize the output voltage signal.

It is a further objective of the present invention to provide a circuit and method for slew rate control to respectively control the rising slew rate and falling slew rate of output voltage signals.

In order to achieve the above objectives, an output driver circuit includes a slew rate control circuit and an output stage. The slew rate control circuit includes a first current source, a second current source, a switch module and a capacitor unit. The output stage is coupled to the slew rate control circuit and outputs an output signal according to a voltage of the capacitor unit, wherein the slew rate of the output signal corresponds to the variation of the voltage.

### BRIEF DESCRIPTION OF THE DRAWINGS

Other objects, advantages, and novel features of the present invention will become more apparent from the following detailed description when taken in conjunction with the accompanying drawings. FIG. 1 shows a block diagram of a conventional output driver circuit.

FIG. 1a shows a circuit diagram of a buffer of a conventional output driver circuit.

FIG. 1b shows a block diagram of a conventional circuit with slew rate control.

FIG. 2 shows a circuit diagram of a circuit for slew rate control according to the first embodiment of the present invention.

FIG. 3 shows a circuit diagram of a circuit for slew rate control according to the second embodiment of the present invention.

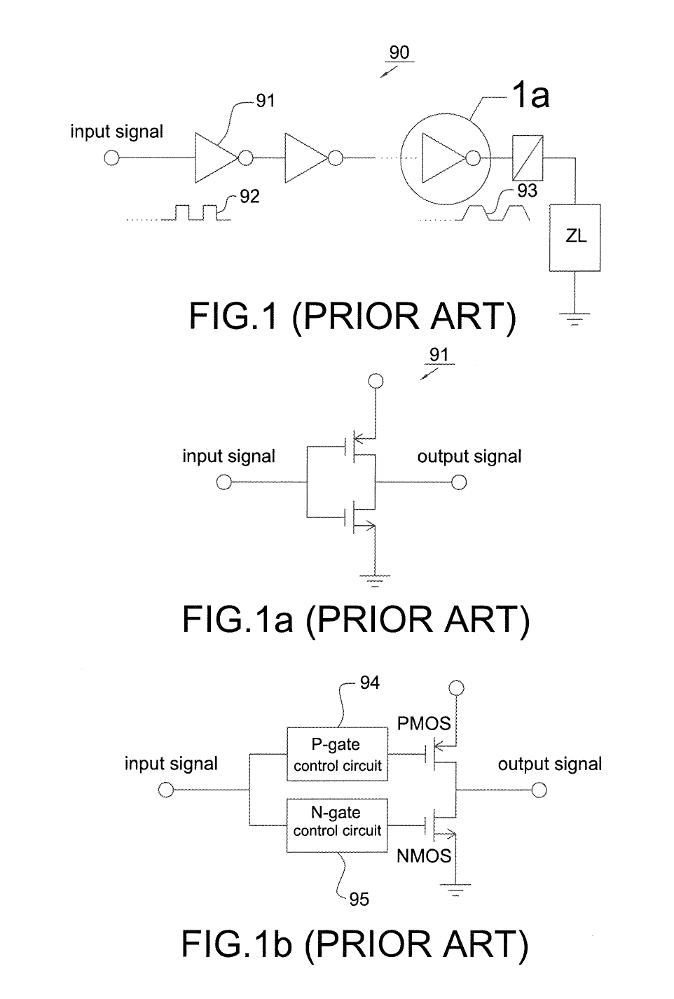

### DETAILED DESCRIPTION OF THE PREFERRED EMBODIMENT

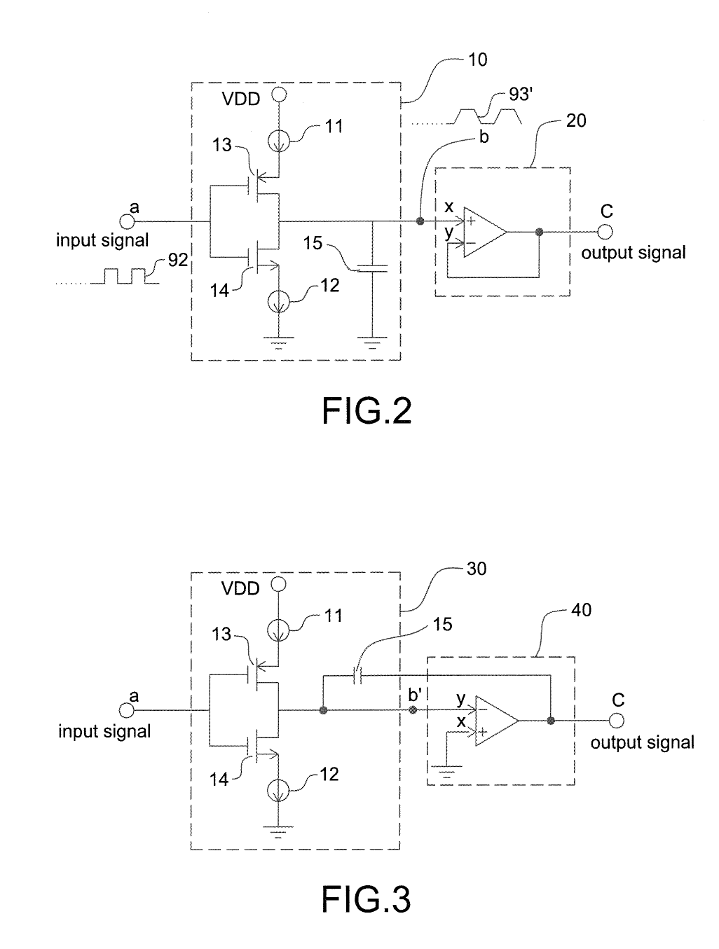

Referring now in detail to exemplary embodiments of the present invention, which are illustrated in the accompanying drawings, in which like numerals designate like elements. Referring to FIG. 2, a circuit for slew rate control of the first embodiment of the present invention includes a slew rate control circuit 10 and an output buffer 20. The slew rate control circuit 10 controls the rising and falling slew rates of an output voltage signal, and the output buffer 20 is able to stably output the output voltage signal. One embodiment of the slew rate control circuit 10 is a charge pump.

In an embodiment, the slew rate control circuit 10 includes a first current source 11, a second current source 12, a switch module which includes two switches 13 and 14, and a capacitor unit 15. The first and the second current sources 11 and 12 are preferably implemented by adjustable current sources, or they comprise a plurality of paralleled current cells and each current cell is respectively controlled by an individual switch. The switches 13 and 14 are preferably transistors. The capacitor unit 15 is preferably implemented by a variable capacitor, or it comprises a plurality of paralleled capacitors and each capacitor is respectively controlled by an individual switch. The capacitor unit 15 has a first terminal and a second terminal, the first terminal is coupled to the output terminal “b” of the slew rate control circuit 10 and the second terminal is coupled to a fixed voltage node, e.g. a ground end.

The slew rate control circuit 10 receives a digital input signal 92 from its input terminal “a”, and the digital input signal 92 controls ON and OFF of the first and the second switches 13 and 14 alternatively, then the output terminal “b” of the slew rate control circuit 10 outputs a digital output signal 93′. When the voltage level of the digital input signal 92 is 1 (i.e. high level), the first switch 13 is in an ON status and the second switch 14 is in an OFF status. Under this circumstance, the first current source 11 provides a charging current to the capacitor unit 15 through the first switch 13 and the voltage of the output terminal “b” will gradually rise, i.e. the voltage of the capacitor unit 15 will gradually rise, and the slew rate control circuit 10 finally outputs the digital output signal 93′ with voltage level 1 (i.e. high level). The rising speed of the voltage of the digital output signal 93′ is called as “voltage rising rate” which is determined by the values of the first current source 11 and the capacitor unit 15. When the current of the first current source 11 is getting larger and/or the capacitance of the capacitor unit 15 is getting smaller, the rising speed of the voltage of the digital output signal 93′ is getting faster, i.e. the voltage rising slew rate is getting larger. On the contrary, if the current of the first current source 11 is getting smaller and/or the capacitance of the capacitor unit 15 is getting larger, the rising speed of the voltage of the digital output signal 93′ is getting slower, i.e. the voltage rising slew rate is getting smaller.

When the voltage level of the digital input signal 92 is 0 (i.e. low level), the first switch 13 is in an OFF status and the second switch 14 is in an ON status. Under this circumstance, the second current source 12 provides a discharging current to the capacitor unit 15 through the second switch 14 and the voltage of the output terminal “b” will gradually fall, i.e. the voltage of the capacitor unit 15 will gradually fall, and the slew rate control circuit 10 finally outputs the digital output signal 93′ with voltage level 0 (i.e. low level). The falling speed of the voltage of the digital output signal 93′ is called as “voltage falling slew rate” which is determined by the values of the second current source 12 and the capacitor unit 15. When the current of the second current source 12 is getting larger and/or the capacitance of the capacitor unit 15 is getting smaller, the falling speed of the voltage of the digital output signal 93′ is getting faster, i.e. the voltage falling slew rate is getting larger. On the contrary, if the current of the second current source 12 is getting smaller and/or the capacitance of the capacitor unit 15 is getting larger, the falling speed of the voltage of the digital output signal 93′ is getting slower, i.e. the voltage falling slew rate is getting smaller. In addition, according to different applications, the values of the first current source 11 and the second current source 12 may be different so as to respectively control the voltage rising slew rate and voltage falling slew rate. Therefore, the voltage rising slew rate and voltage falling slew rate of the output terminal “b” of the slew rate control circuit 10 can be controlled by merely adjusting at least one of the first current source 11, the second current source 12 and the capacitor unit 15.

The output stage 20 is preferably an operational amplifier with negative feedback. The present embodiment utilizes the close loop characteristics of the operational amplifier to drive the digital output signal 93′ to the output terminal “c” of the output stage 20. With such arrangement, the voltage in the output terminal “c” of the output stage 20 will not be influenced by the load connected next to the output terminal “c” of the output stage 20. The control circuit of the present invention for respectively controlling the voltage rising slew rate and voltage falling slew rate can be realized and the output voltage signal can be stabilized according to this structure.

Referring to FIG. 3, it shows a circuit and method for slew rate control according to the second embodiment of the present invention, the circuit includes a slew rate control circuit 30 and an output stage 40. The differences between the second and the first embodiments are in that a negative input terminal “y” of the output stage 40 is coupled to the output terminal “b” of the slew rate control circuit 30 and a positive input end “x” of the output stage 40 is coupled to ground. In addition, the first terminal of the capacitor unit 15 is coupled to the output terminal “b′” of the slew rate control circuit 30, and its second terminal is coupled to the output terminal “c” of the output stage 40 so as to form a negative feedback loop. In such arrangement, the voltage rising slew rate and voltage falling slew rate can be respectively controlled by the slew rate control circuit 30, and the output voltage signals outputted from the output stage 40 will not be influenced by the load connected next to it according to the close loop characteristics of the output stage 40.

Although the invention has been explained in relation to its preferred embodiment, it is not used to limit the invention. It is to be understood that many other possible modifications and variations can be made by those skilled in the art without departing from the spirit and scope of the invention as hereinafter claimed.

What is claimed is:

1. An apparatus for controlling a slew rate of an output signal, comprising:
a slew rate control circuit comprising:
a first current source;
a second current source; and
a switch module for controlling the first current source to charge an output terminal of the slew rate control circuit and controlling the second current source to discharge the output terminal of the slew rate control circuit according to an input signal;
and
an output stage, coupled to the slew rate control circuit, to output the output signal according to a voltage of the capacitor unit;
wherein the slew rate of the output signal is corresponding to a voltage variation of the capacitor unit.

2. The apparatus of claim 1, wherein the slew rate control circuit comprises a capacitor unit coupled to the output terminal of the slew rate control circuit.

3. The apparatus of claim 2, wherein the output stage comprises an operational amplifier with negative feedback.

4. The apparatus of claim 3, wherein the capacitor unit is coupled to a positive input terminal of the operational amplifier.

5. The apparatus of claim 3, wherein the capacitor unit is coupled between a negative input terminal and an output terminal of the operational amplifier.

6. The apparatus of claim 2, wherein at least one of the first current source and the second current source and the capacitor unit is adjustable.

7. An apparatus for outputting an output signal according to an input signal, comprising:
a slew rate control circuit:
a first current source;
a second current source; and
a switch module, for controlling the first current source to charge an output terminal of the slew rate control circuit and controlling the second current source to discharge the output terminal of the slew rate control circuit according to the input signal;
and
an output stage, coupled to the slew rate control circuit for outputting the output signal;
wherein a slew rate of the output signal corresponds to the capacitor unit and at least one of the first and the second current sources.

8. The apparatus of claim 7, wherein the slew rate control circuit comprises a capacitor unit coupled to the output terminal of the slew rate control circuit.

9. The apparatus of claim 8, herein at least one of the first current source, the second current source and the capacitor unit is adjustable.

10. The apparatus of claim 8, wherein the capacitor unit is a variable capacitor.

11. The apparatus of claim 8, wherein the capacitor unit comprises a plurality of capacitors, and each capacitor is controlled by a corresponding switch.

12. The apparatus of claim 7, wherein at least one of the first and the second current sources comprises a plurality of current cells, and each current cell is controlled by a corresponding switch.

13. The apparatus of claim 7, wherein the output stage comprises an operational amplifier with negative feedback.

14. The apparatus of claim 7, wherein at least one of the first current source and the second current source is adjustable.

15. A slew rate control method applied to an output signal, comprising:
providing a first current to charge an output terminal of an slew rate control circuit;
providing a second current to discharge the output terminal of the slew rate control circuit; and
outputting the output signal according to a voltage of the output terminal of the slew rate control circuit;
wherein a slew rate of the output signal corresponds to the first current and the second current.

16. The method of claim 15, wherein the slew rate of the output signal is corresponding to a voltage variation of the output terminal of slew rate control circuit.

17. The method of claim 15, wherein the slew rate control circuit comprises a capacitor unit coupled to the output terminal of slew rate control circuit.

18. The method of claim 17, wherein the capacitor unit comprises a plurality of capacitors and corresponding switches.

19. The method of claim 17, wherein at least one of the values of the first current, the second current and the capacitor unit is adjustable.

20. The method of claim 15, further comprising:
adjusting at least one of the first current, the second current, and a capacitance of the output terminal of the slew rate control circuit to adjust the slew rate of the output signal.
